(19) United States
(12) Patent Application Publication
(10) Pub. No.: US 2007/0184573 A1
(43) Pub. Date: Aug. 9, 2007

(54) Method of making a thermally treated coated article with transparent conductive oxide (TCO) coating for use in a semiconductor device

(75) Inventor: Alexey Krasnov, Canton, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp.,, Auburn Hills, MI (US)

(21) Appl. No.: 11/349,346

(22) Filed: Feb. 8, 2006

(51) Int. Cl. H01L 21/44

(52) U.S. Cl. 438/98; 438/609; 438/660

(57) ABSTRACT

A method of making a coated article including a transparent conductive oxide (TCO) film supported by a glass substrate is provided. Initially, an amorphous metal oxide film is sputter-deposited onto a glass substrate, either directly or indirectly. The glass substrate with the amorphous film and a semiconductor film thereon is then thermally treated at high temperature(s). The thermal treating causes the amorphous film to be transformed into a crystalline transparent conductive oxide (TCO) film. The heat used in the thermal treating causes the amorphous film to turn into a crystalline film, causes the visible transmission of the film to increase, and/or causes the film to become electrically conductive.

This invention relates to a method of making a thermally treated coated article including a transparent conductive oxide (TCO) film supported by a glass substrate. Coated articles according to certain example non-limiting embodiments of this invention may be used in semiconductor applications including photovoltaic devices such as solar cells, or in other applications such as oven doors, defrosting windows, or other types of windows in certain example instances.

### BACKGROUND AND SUMMARY OF EXAMPLE EMBODIMENTS OF INVENTION

Conventional methods of forming TCOs on glass substrates require high glass substrate temperatures. Such methods include chemical pyrolysis where precursors are sprayed onto the glass substrate at approximately 400 to 600 degrees C., and vacuum deposition where the glass substrate is kept at about 100 to 300 degrees C. It is often not desirable to require such high glass substrate temperatures for TCO deposition processing.

Sputter deposition of a TCO at approximately room temperature would be desirable, given that most float glass manufacturing platforms are not equipped with in-situ heating systems. Thus, it would be an achievement in the art if a technique for sputter-depositing TCOs could be realized that would result in a sufficiently conductive film. However, a problem associated with low-temperature sputter deposition is the low atom mobility of the resulting layer on the glass substrate. This limits the ability of species to find their optimal positions, thereby reducing film quality due to less than desirable crystallinity. The low atom mobility is particularly problematic for dopant atoms which are often introduced to a stoichiometric film to produce free electrons. At low deposition temperatures, the dopant atoms tend to cluster such that their efficiency becomes reduced. Thus, low-temperature sputtering of TCOs has not heretofore been practical.

As mentioned above, typical methods for forming TCO films on glass include chemical pyrolysis where precursors are sprayed onto the glass substrate at approximately 400 to 600 degrees C., and vacuum deposition where the glass substrate is kept at about 100 to 300 degrees C. In addition to the initial high temperature needs, an another problem is that TCO films such as SnO₂:F (fluorine doped tin oxide) formed on glass substrates by chemical pyrolysis suffer from non-uniformity and thus may be unpredictable and/or inconsistent with respect to certain optical and/or electrical properties.

Additionally, it has been found that glass substrates supporting certain sputter-deposited TCOs cannot be thermally tempered without the TCOs suffering a significant loss in electrical conductivity. Glass tempering temperatures (e.g., 580 degrees C. and higher) of typical sputter-deposited films causes a rapid conductivity drop in certain TCOs (e.g., sputter-deposited zinc oxide inclusive TCOs). Thus, there is a problem associated with heat treating a TCO after it has been formed.

Thus, it will be appreciated that there exists a need in the art for an improved technique or method of forming glass substrates including a TCO film/coating thereon that can result in an effective and/or efficient glass substrate with a TCO film thereon, which may be used in a variety of different applications such as photovoltaic devices or the like.

In certain example embodiments of this invention, a method is provided for making a thermally treated coated article such as a photovoltaic device including a glass substrate with a TCO film thereon. Initially, an amorphous metal oxide film is sputter-deposited onto a glass substrate at approximately room temperature (not at a high temperature), either directly or indirectly. In certain example embodiments, the sputter-deposited amorphous metal oxide film may be of or include an oxide of Sn and/or Sb (e.g., SnOₓ:Sb). As sputter-deposited at about room temperature, the metal oxide film is rather high with respect to visible light absorption, has a high sheet resistance (i.e., not truly conductive), and is amorphous. Thus, it is not a TCO as deposited at room temperature. In certain example embodiments, a photoelectric conversion layer(s) such as one or more of CdS, CdTe, or the like may be formed on the glass substrate over the substantially amorphous sputter-deposited metal oxide film. The glass substrate with the substantially amorphous film and photoelectric conversion layer(s) thereon is then thermally treated (e.g., this thermal treatment may be part of a process of making a photovoltaic device in certain example embodiments). The thermal treating typically involves heating the glass substrate with the amorphous film and photoelectric conversion layer(s) thereon at a temperature of at least about 175 degrees C., more preferably at least about 200 degrees C., even more preferably at least about 300 degrees C., sometimes at least about 400 degrees C., and sometimes at least about 500 or 550 degrees C. (e.g., from about 400-630 degrees C. in certain example instances).

The thermal treatment (e.g., annealing) may be performed for at least about 10 minutes in certain example embodiments, more preferably at least about 15 minutes, even more preferably at least about 20 minutes, and possibly at least one hour (e.g., from about 10-30 minutes, or even for several hours) in certain example embodiments of this invention. For instance, in CdTe/CdS photovoltaic devices, the thermal treatment may involve annealing or heat treating during a chlorine treatment step, using temperatures of from about 400-630 degrees C., whereas in silicon (e.g., a-Si) based photovoltaic devices the thermal treatment may involve several hours of treatment at about 150-250 degrees C., e.g., or at about 200 degrees C.

It has been found that the thermal treating causes the amorphous non-conductive film to be transformed into a crystalline transparent conductive oxide (TCO) film. In other words, the heat used in the thermal treating of the product causes the amorphous film to turn into a crystalline film, causes the visible transmission of the film to increase, and causes the film to become electrically conductive. In short, the thermal treatment activates the substantially amorphous film and converts it into a transparent conductive film.

In certain example embodiments of this invention, the substantially amorphous film prior to the heat treating and the crystalline TCO following the heat treating may be of or include SnOₓ:Sb (x may be from about 0.5 to 2, more preferably from about 1 to 2, and sometimes from about 1 to 1.95). The film may be oxygen deficient (substoichiometric in certain instances). The Sn and Sb may be co-sputtered in an oxygen inclusive atmosphere (e.g., a mixture of oxygen and argon) to form the substantially amorphous film in certain example embodiments of this invention, with the Sb being provided to increase conductivity of the crystalline film following heat treating. In certain example embodiments, the Sb is provided for doping purposes, and can make up from about 0.001 to 30% (weight %) of the substantially amorphous and/or crystalline metal oxide film (from preferably from about 1 to 15%, with an example being about 8%). If the Sb content is higher than this, the lattice may be disturbed too much and mobility of electrons may be disturbed thereby hurting conductivity of the film, whereas if less than this amount of Sb is provided then the conductivity may not be as good in the crystalline film.

In other example embodiments of this invention, the thin film as originally sputter-deposited on the glass substrate may be of or include a zinc oxide based film including Al as a primary dopant and Ag as a co-dopant. The use of both the primary dopant (e.g., Al or the like) and the co-dopant (e.g., Ag or the like) in depositing (e.g., sputter-depositing) the substantially amorphous thin film prevents or reduces the formation of compensating native defects in a wide-bandgap semiconductor material during the impurity introduction by controlling the Fermi level at or proximate the edge of the growth. After being captured by surface forces, atoms start to migrate and follow the charge neutrality principle. The Fermi level is lowered at the growth edge by the addition of a small amount of acceptor impurity (such as Ag) so it prevents or reduces the formation of the compensating (e.g., negative in this case) species, such as zinc vacancies. After the initial stage of the semiconductor layer formation, the mobility of atoms is reduced and the probability of the point defect formation is primarily determined by the respective energy gain. Silver atoms for example in this particular example case tend to occupy interstitial sites where they play a role of predominantly neutral centers, forcing Al atoms to the preferable zinc substitutional sites, where Al plays the desired role of shallow donors, thus eventually raising the Fermi level. In addition, the provision of the co-dopant promotes declustering of the primary dopant, thereby freeing up space in the metal sublattice and permitting more Al to function as a charge carrier so as to improve conductivity of the film. Accordingly, the use of the co-dopant permits the primary dopant to be more effective in enhancing conductivity of the resulting TCO inclusive film following heat treatment, without significantly sacrificing visible transmission characteristics. Furthermore, the use of the co-dopant improves crystallinity of the TCO inclusive film and thus the conductivity thereof, and grain size may also increase which can lead to increased mobility.

In an example embodiment (e.g., which may be used in a-Si photovoltaic devices or the like), a sputter-deposited zinc oxide based thin film includes Al as a primary dopant and Ag as a co-dopant. In this respect, the Al is the primary charge provider. It has surprisingly been found that the introduction of Ag to ZnAlOₓ promotes declustering of the Al and permits more Al to function as a donor thereby improving crystallinity and conductivity of the film. In the case of introducing Ag as the co-dopant (acceptor) into ZnO, Ag facilitates the introduction of the primary donor dopant (Al). Certain example embodiments of this invention may also use the ability of silver to promote the uniform or substantially uniform distribution of donor-like dopants in wide-bandgap II-VI compounds, thereby allowing one to increase the effective dopant concentration in a poly-crystalline film. While silver is used as a co-dopant in certain example embodiments of this invention, it is possible to use another Group IB, IA or V element such as Cu or Au instead of or in addition to silver as the co-dopant.

In certain example embodiments of this invention, there is provided a a method of making a heat treated device including a semiconductor film and a transparent conductive metal oxide (TCO) film on a glass substrate, the method comprising: providing a glass substrate; sputter-depositing a substantially amorphous metal oxide based film comprising Sn and Sb, and/or ZnAlOₓ:Ag, on the glass substrate at approximately room temperature; forming a semiconductor film on the glass substrate over the substantially amorphous metal oxide based film; heat treating the glass substrate with the substantially amorphous metal oxide based film comprising Sn and Sb, and/or ZnAlOₓ:Ag, and the semiconductor film thereon; and wherein heat used in said heat treating causes the substantially amorphous film to transform into a substantially crystalline film comprising Sn and Sb, and/or ZnAlOₓ:Ag, and wherein the substantially crystalline film is transparent to visible light and electrically conductive.

### BRIEF DESCRIPTION OF THE DRAWINGS

FIG. 1 is a flowchart illustrating a method of making a thermally treated coated article according to an example embodiment of this invention, wherein the coated article may be used in connection with a semiconductor device such as a photovoltaic device.

FIG. 2 is a schematic diagram illustrating the method of FIG. 1 using cross sectional views according to an example embodiment of this invention.

### DETAILED DESCRIPTION OF EXAMPLE EMBODIMENTS OF THE INVENTION

Coated articles including conductive layer(s) according to certain example non-limiting embodiments of this invention may be used in applications including semiconductor devices such as photovoltaic devices, and/or in other applications such as oven doors, defrosting windows, display applications, or other types of windows in certain example instances. For example and without limitation, the transparent conductive oxide (TCO) layers discussed herein may be used as electrodes in solar cells, as heating layers in defrosting windows, as solar control layers in windows, and/or the like. For example, the TCO film may be used as a front electrode or front contact in a photovoltaic device in certain example instances.

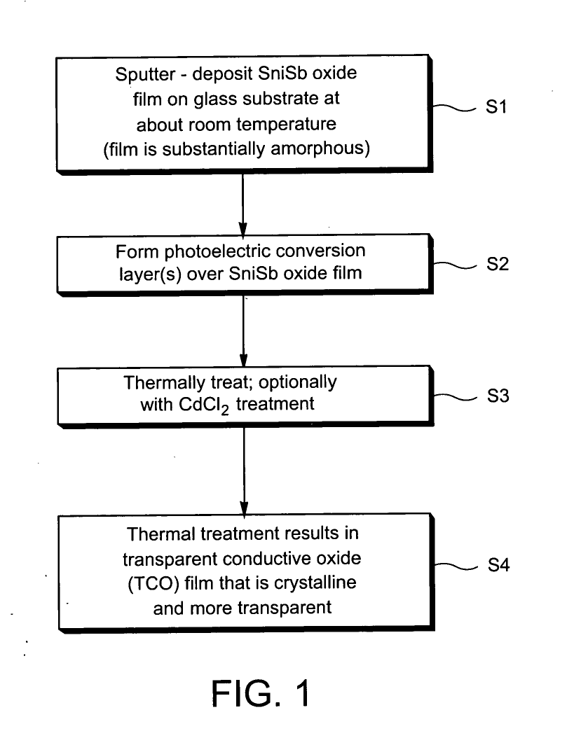

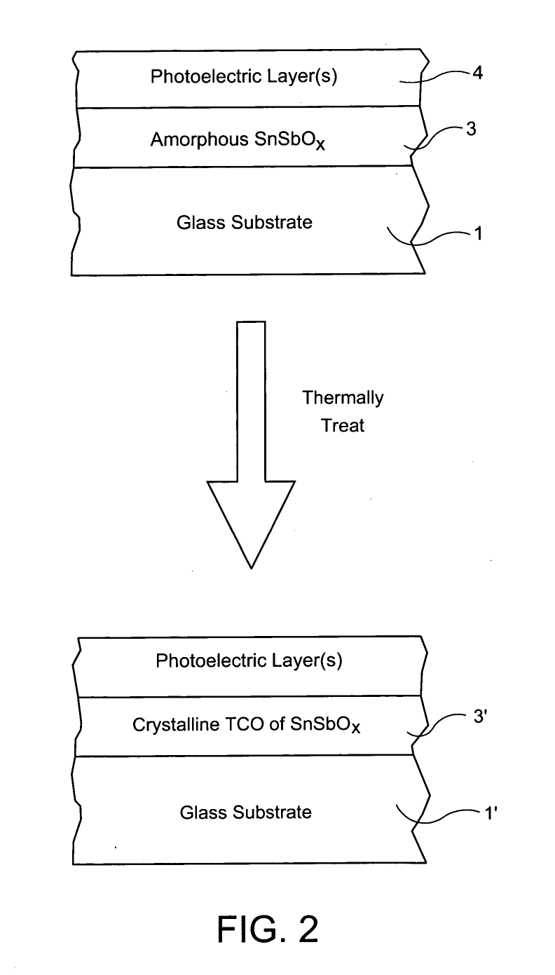

FIG. 1 is a flowchart illustrating certain steps performed in making a coated article according for use in a semiconductor device according to an example embodiment of this invention, whereas FIG. 2 illustrates this example embodiment in terms of a cross sectional schematic view.

Referring to FIGS. 1-2, an example of this invention will be described. Initially, an amorphous or substantially amorphous metal oxide thin film 3 is sputter-deposited onto a glass substrate 1 at approximately room temperature (S1 in FIG. 1). It is possible that other layer(s) may be provided on the substrate 1 under film 3, although the film 3 may be deposited directly onto the substrate in certain example embodiments. The film 3 is considered “on” and “supported by” the substrate 1 regardless of whether other layer(s) are provided therebetween. In certain example embodiments, the sputter-deposited substantially amorphous metal oxide film 3 may be of or include an oxide of Sn and/or Sb (e.g., SnOₓ:Sb). As sputter-deposited, the metal oxide film 3 may have a visible light transmission of less than 70%, may have a rather high sheet resistance (i.e., not be truly conductive), and is substantially amorphous or amorphous because the glass substrate was at approximately room temperature when the sputtering was performed.

After the substantially amorphous metal oxide thin film 3 is sputter-deposited onto the glass substrate 1 in S1, one or more semiconductor layers is/are formed on the glass substrate 1 over the substantially amorphous metal oxide film 3 in S2. In certain example embodiments of this invention, the semiconductor film (including one or more layers) 4 formed in this step may be a photoelectric or photovoltaic film. For example, in making a CdSe thin film solar cell, the semiconductor film 4 may include a CdS inclusive layer over the metal oxide thin film 3, and then a CdTe inclusive layer over the CdS inclusive layer. In other example embodiments, the semiconductor film 4 may be of or include a silicon based layer such as an a-Si layer or a crystalline silicon layer. The semiconductor film may be deposited in any suitable manner (e.g., CVD or PECVD). For example and without limitation, the CdTe may be electrodeposited from an aqueous bath contain cadmium and tellurium ions; and the CdS layer may be deposited using a vacuum deposition process or a narrow reaction gap process. Instead of a CdS/CdTe structure for the semiconductor film 4, other semiconductors may instead be used; for instance CdS/HgCdTe, CdS/CdZnTe, CdS/ZnTe, CdS/CIS, CdS/CIGS, polycrystalline Si or a-Si may be used as or in semiconductor film 4. Optionally, it is possible to provide an additional layer(s) between films 3 and 4 in certain example embodiments of this invention.

Following steps S1 and S2, the glass substrate 1 with the substantially amorphous metal oxide (MOx) thin film 3 and the semiconductor film 4 thereon is thermally treated (S3 in FIG. 1). The thermal treatment typically involves heating the glass substrate with the amorphous film 3 and photoelectric conversion layer(s) or semiconductor film 4 thereon at a temperature of at least about 175 degrees C., more preferably at least about 200 degrees C., even more preferably at least about 300 degrees C., sometimes at least about 400 degrees C., and sometimes at least about 500 or 550 degrees C. (e.g., from about 400-630 degrees C. in certain example instances). The thermal treatment (e.g., annealing) may be performed for at least about 10 minutes in certain example embodiments, more preferably at least about 15 minutes, even more preferably at least about 20 minutes, and possibly at least one hour (e.g., from about 10-30 minutes, or even for several hours) in certain example embodiments of this invention. For instance, in CdTe/CdS photovoltaic devices, the thermal treatment may involve annealing or heat treating during a chlorine treatment step, using temperatures of from about 400-630 degrees C., whereas in silicon (e.g., a-Si) based photovoltaic devices the thermal treatment may involve several hours of treatment at about 150-250 degrees C., e.g., or at about 200 degrees C. For instance, in making a CdTe photovoltaic device, a CdCl₂ based or inclusive solution may be coated on the device over at least the CdTe, CdS and metal oxide films (e.g., CdCl₂ in methanol); and the coating may then be dried and then heated to a high heat treating temperature (e.g., 400-600 degrees C.) for about twenty minutes or any other suitable time. In certain example embodiments, the glass/MOx/CdS/CdTe structure may be annealed with a CdCl₂ or other heat treatment to increase grain size, passivate grain boundaries, increase alloying, and reduce lattice mismatch between the CdS layer and the CdTe layer. Following the heat treating, the glass 1′ may be tempered or heat strengthened in certain example embodiments.

The heat used during the thermal treating step S3 causes the substantially amorphous non-conductive metal oxide film 3 to be transformed into a crystalline transparent conductive oxide (TCO) film 3′ (see S4 in FIG. 1; and FIG. 2). In other words, the heat used in the thermal treatment causes the substantially amorphous film 3 to turn into a crystalline film 3′, causes the visible transmission of the film to increase (e.g., to a level above 70%), and causes the film to become electrically conductive. In short, the thermal treating activates the metal oxide film so that TCO film 3′ is provided following the thermal treating.

In certain example embodiments, the thermal treating causes the visible transmission of the film 3 to increase by at least about 5%, more preferably by at least about 10%. In certain example embodiments, the thermal treating causes the sheet resistance (Rₛ) of the film 3 to drop by at least about 20 ohms/square, more preferably by at least about 50 ohms/square, and most preferably by at least about 100 ohms/square. Electrical conductivity can be measured in terms of sheet resistance (Rₛ). The TCO films 3′ discussed herein (following the heat treating) have a sheet resistance (Rₛ) of no greater than about 200 ohms/square, more preferably no greater than about 100 ohms/square, and most preferably from about 5-100 ohms/square. In certain example embodiments, conductivity can be caused by creating nonidealities or point defects in crystal structure of a film to generate electrically active levels thereby causing its sheet resistance to drop significantly into the range discussed above. This can be done by using an oxygen deficient atmosphere during crystal growth and/or by doping (e.g., with Sb).

In certain example photovoltaic applications, the heat treated coated may additionally include a back metal contact electrode, and the article discussed above may be used in such a photovoltaic device.

In certain example embodiments of this invention, the amorphous metal oxide film 3 prior to heat treating and the crystalline TCO film 3′ following heat treating may be of or include SnOₓ:Sb (x may be from about 0.5 to 2, more preferably from about 1 to 2, and sometimes from about 1 to 1.95). The film may be oxygen deficient in certain example embodiments (substoichiometric in certain instances). The Sn and Sb may be co-sputtered in an oxygen inclusive atmosphere (e.g., a mixture of oxygen and argon) to form the amorphous metal oxide film 3 in certain example embodiments of this invention, with the Sb being provided to increase conductivity of the crystalline film following heat treating. The co-sputtering to form metal oxide film 3 may be performed by sputtering a ceramic target(s) of SnSbOₓ in certain example embodiments of this invention (e.g., in a gaseous atmosphere include argon and/or oxygen gas); or alternatively the co-sputtering may be performed by sputtering a SnSb target(s) in an atmosphere including argon, oxygen and possibly fluorine gases.

In certain example embodiments, the Sb is provided for doping purposes, and can make up from about 0.001 to 30% (weight %) of the amorphous and/or crystalline metal oxide film 3 (from preferably from about 1 to 15%, with an example being about 8%). If the Sb content is higher than this, the lattice is disturbed too much and mobility of electrons is also disturbed thereby hurting conductivity of the film, whereas if less than this amount of Sb is provided then the conductivity is not as good in the crystalline film. In certain example embodiments of this invention, the amorphous 3 and/or crystalline film 3′ has a Sn content of from about 20-95%, more preferably from about 30-80%.

While a TCO of or including an oxide of SnOₓ:Sb is preferred for the crystalline TCO film 3′ and the substantially amorphous film 3 in certain example embodiments of this invention, other materials may instead be used. For example and without limitation, it is possible to use ZnAlOₓ:Ag as a TCO (for layers 3 and 3′ in the FIG. 1-2 embodiment) in other example embodiments of this invention (e.g., in a-Si or Si photovoltaic devices). For purposes of example, the substantially amorphous film 3 may be zinc oxide based, the primary dopant may be Al or the like, and the co-dopant may be Ag or the like. In such an example case, Al is the primary charge carrier dopant. However, if too much Al is added (without Ag), its effectiveness as a charge carrier is compromised because the system compensates Al by generating native acceptor defects (such as zinc vacancies). Also, at low substrate temperatures such as room temperature, more clustered electrically inactive (yet optically absorbing) defects tend to occur. However, when Ag is added as a co-dopant, this promotes declustering of the Al and permits more Al to function as a charge generating dopant (Al is more effective when in the Zn substituting sites). Thus, the use of the Ag permits the Al to be a more effective charge generating dopant in the TCO inclusive film 3. Accordingly, the use of Ag in ZnAlO is used to enhance the electrical properties of the film.

In certain example embodiments of this invention, the amount of primary dopant (e.g., Al) in the film 3 may be from about 0.5 to 7%, more preferably from about 0.5 to 5%, and most preferably from about 1 to 4% (atomic %). Moreover, in certain example embodiments of this invention, the amount of co-dopant (e.g., Ag) in the film 3 may be from about 0.001 to 3%, more preferably from about 0.01 to 1%, and most preferably from about 0.02 to 0.25% (atomic %). In certain example instances, there is more primary dopant in the film than co-dopant, and preferably there is at least twice as much primary dopant in the film than co-dopant (more preferably at least three times as much, and most preferably at least 10 times as much). Moreover, there is significantly more Zn and O in the film 3 than both Al and Ag, as the film 3 may be zinc oxide based—various different stoichiometries may be used for film 3.

The use of both the primary dopant (e.g., Al) and the co-dopant (e.g., Ag) in depositing (e.g., sputter-depositing) the TCO inclusive film (e.g., ZnAlOₓ:Ag) 3 prevents or reduces the formation of compensating native defects in a wide-bandgap semiconductor material during the impurity introduction by controlling the Fermi level at or proximate the edge of the growth. After being captured by surface forces, atoms start to migrate and follow the charge neutrality principle. The Fermi level is lowered at the growth edge by the addition of a small amount of acceptor impurity (such as Ag) so it prevents or reduces the formation of the compensating (negative in this case) species, such as zinc vacancies. After the initial stage of the semiconductor layer formation, the mobility of atoms is reduced and the probability of the point defect formation is primarily determined by the respective energy gain. Silver atoms in this particular case tend to occupy interstitial sites where they play role of predominantly neutral centers, forcing Al atoms to the preferable zinc substitutional sites, where Al plays the desired role of shallow donors, thus eventually raising the Fermi level. In addition, the provision of the co-dopant (Ag) promotes declustering of the primary dopant (Al), thereby freeing up space in the metal sublattice of the film 3 and permitting more primary dopant (Al) to function as a charge provider so as to improve conductivity of the film. Accordingly, the use of the co-dopant (Ag) permits the primary dopant (Al) to be more effective in enhancing conductivity of the TCO inclusive film 3, without significantly sacrificing visible transmission characteristics. Furthermore, the use of the co-dopant surprisingly improves crystallinity of the TCO inclusive film 3 and thus the conductivity of TCO film 3′, and grain size of the crystalline film 3′ may also increase which can lead to increased mobility.

In certain example embodiments, the sputtering target for use in sputter-depositing at about room temperature the ZnAlOₓ:Ag film 3 may be made of or include ZnAlAg, where Zn is the primary metal of the target, Al is the primary dopant, and Ag is the co-dopant. Thus, with respect to atomic % content of the target, the target is characterized by Zn>Al>Ag, where at least 50% of the target is made up of Zn (more preferably at least 70%, and most preferably at least 80%). Moreover, the amount of primary dopant (e.g., Al) in the target may be from about 0.5 to 7%, more preferably from about 0.5 to 5%, and most preferably from about 1 to 4% (atomic %); and the amount of co-dopant (e.g., Ag) in the target (e.g., magnetron rotating target) may be from about 0.001 to 3%, more preferably from about 0.01 to 1%, and most preferably from about 0.02 to 0.25% (atomic %). When the target is an entirely metallic or substantially metallic target, the target is typically sputtered in an atmosphere include oxygen gas (e.g., O₂). In certain example embodiments, the atmosphere in which the target is sputtered may include a mixture of oxygen and argon gas. The oxygen from the atmosphere contributes to forming the “oxide” nature of the film 3 on the substrate. It is also possible for other gases (e.g., nitrogen) to be present in the atmosphere in which the target is sputtered, and thus some of this may end up in the film 3 on the substrate. In other example embodiments, the sputtering target 5 may be a ceramic target. For example, the target may be of or include ZnAlAgOₓ. A ceramic target may be advantageous in this respect because less oxygen gas would be required in the atmosphere in which the target is sputtered (e.g., and more Ar gas for example could be used).

While ZnAlAgOₓ is mentioned above, it is possible that the ZnAlAgOₓ (or ZnAlOₓ:Ag) may be replaced with ZnAlOₓ in any embodiment of this invention, for the layer and/or target. For ZnAlOₓ for film 3 and/or target, zinc oxide may be doped with from Al in certain example instances.

While silver is discussed as a co-dopant in certain example embodiments of this invention, it is possible to use another Group IB, IA or V element such as Cu or Au instead of or in addition to silver as the co-dopant. Moreover, while Al is discussed as a primary dopant in certain example embodiments of this invention, it is possible to use another material such as Mn (instead of or in addition to Ag) as the primary dopant for the film 3.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

For example, in certain example embodiments an optically and/or mechanically matching layer(s) or layer stack may be provided between the film 3 (or 3′) and the glass substrate 1 (or 1′). Moreover, it is possible to form other layer(s) over the film 3 (or 3′) in certain example embodiments of this invention. In other example embodiments of this invention, the Sb may be omitted from film 3 and/or 3′, or another dopant(s) may be used instead of or in addition to the Sb in the film.

1. A method of making a heat treated device including a semiconductor film and a transparent conductive metal oxide (TCO) film on a glass substrate, the method comprising:
providing a glass substrate;
sputter-depositing a substantially amorphous metal oxide based film comprising Sn and Sb on the glass substrate at approximately room temperature;
forming a semiconductor film on the glass substrate over the substantially amorphous metal oxide based film;
heat treating the glass substrate with the substantially amorphous metal oxide based film comprising Sn and Sb and the semiconductor film thereon; and
wherein heat used in said heat treating causes the substantially amorphous film to transform into a substantially crystalline film comprising Sn and Sb, and wherein the substantially crystalline film is transparent to visible light and electrically conductive.

2. The method of claim 1, wherein heat used in said heat treating causes sheet resistance of the substantially amorphous film to decrease by at least about 20 ohms/square.

3. The method of claim 1, wherein heat used in said heat treating causes sheet resistance of the substantially amorphous film to decrease by at least about 50 ohms/square.

4. The method of claim 1, wherein the heat treating comprises heat treating the glass substrate with the substantially amorphous metal oxide based film comprising Sn and Sb and the semiconductor film thereon at a temperature of at least about 200 degrees C.

5. The method of claim 1, wherein the heat treating comprises heat treating the glass substrate with the substantially amorphous metal oxide based film comprising Sn and Sb and the semiconductor film thereon at a temperature of from about 400-630 degrees C.

6. The method of claim 1, wherein the substantially crystalline film has a sheet resistance of no greater than about 100 ohms/square.

7. The method of claim 1 wherein the substantially crystalline film comprises an oxide of Sn, and wherein Sb content of the crystalline film is from about 0.001 to 30%.

8. The method of claim 1 wherein the substantially crystalline film comprises an oxide of Sn, and wherein Sb content of the crystalline film is from about 1 to 15%.

9. The method of claim 1, wherein another layer is provided on the glass substrate so as to be located between the glass substrate and the crystalline film.

10. The method of claim 1, wherein the crystalline film comprises SnOₓ:Sb and is at least about 70% transparent to visible light.

11. The method of claim 1, wherein said heating treatment is part of a chlorine treatment step in making a photovoltaic device.

12. The method of claim 1, wherein said sputter-depositing comprises sputtering at least one ceramic sputtering target comprising an oxide of Sn:Sb.

13. The method of claim 1, wherein the device is a photovoltaic device, wherein the substantially crystalline film comprising Sn and Sb is used as a front electrode or contact of the photovoltaic device, and wherein the semiconductor film is a photovoltaic film.

14. A method of making a photovoltaic device including the method of claim 1.

15. A method of making a heated treated device including a semiconductor film and a transparent conductive metal oxide (TCO) film on a glass substrate, the method comprising:
providing a glass substrate;
sputter-depositing a substantially amorphous metal oxide based film comprising ZnAlOₓ:Ag and/or ZnAlOₓ on the glass substrate at approximately room temperature;
forming a semiconductor film on the glass substrate over the substantially amorphous metal oxide based film;
heat treating the glass substrate with the substantially amorphous metal oxide based film comprising ZnAlOₓ:Ag and/or ZnAlOₓ and the semiconductor film thereon; and
wherein heat used in said heat treating causes the substantially amorphous film to transform into a substantially crystalline film comprising ZnAlOₓ:Ag and/or ZnAlOₓ, and wherein the substantially crystalline film is transparent to visible light and electrically conductive.

16. The method of claim 15, wherein heat used in said heat treating causes sheet resistance of the substantially amorphous film to decrease by at least about 20 ohms/square.

17. A method of making a heated treated device including a semiconductor film and a transparent conductive metal oxide (TCO) film on a glass substrate, the method comprising:
providing a glass substrate;
sputter-depositing a metal oxide based film comprising ZnAlOₓ:Ag and/or ZnAlOₓ on the glass substrate at approximately room temperature;
forming a semiconductor film on the glass substrate over the metal oxide based film;
heat treating the glass substrate with the metal oxide based film comprising ZnAlOₓ:Ag and/or ZnAlOₓ, and the semiconductor film thereon, so that following said heat treating the film comprising ZnAlOₓ:Ag and/or ZnAlOₓ is electrically conductive and substantially transparent to at least visible light.

18. The method of claim 17, wherein the device is a photovoltaic device, wherein the film comprising ZnAlOₓ:Ag and/or ZnAlOₓ is used as a front electrode or contact of the photovoltaic device, and wherein the semiconductor film is a photovoltaic film.
